(19) United States
(12) Patent Application Publication
(10) Pub. No.: US 2019/0066812 A1
(43) Pub. Date: Feb. 28, 2019

(54) TDDB PERCOLATION CURRENT INDUCED E-FUSE STRUCTURE AND METHOD OF PROGRAMMING SAME

(71) Applicant: GLOBALFOUNDRIES INC., Grand Cayman (KY)

(72) Inventors: Kong Boon Yeap, Clifton Park, NY (US); Tian Shen, Clifton Park, NY (US); Ronald Gene Filippi, JR., Wappingers Falls, NY (US); Seungman Choi, Loudonville, NY (US); Linjun Cao, Ballston Lake, NY (US)

(21) Appl. No.: 15/685,667

(22) Filed: Aug. 24, 2017

(51) Int. Cl. G11C 17/18; G11C 17/16

(52) U.S. Cl. CPC G11C 17/18; G11C 17/16

(57) ABSTRACT

An e-fuse structure including a circuit having an e-fuse operably coupling the circuit to a power source, and a redundant circuit for operably coupling the power source in response to opening of the e-fuse, wherein the e-fuse opens in response to a time-dependent dielectric breakdown (TDDB) percolation current in proximity to the circuit migrating through the e-fuse. A method of programming such an e-fuse structure is also disclosed.

### TECHNICAL FIELD

The subject matter disclosed herein relates to self-triggering e-fuses of semiconductors. More specifically, various aspects described herein relate to a time-dependent dielectric breakdown (TDDB) percolation current induced e-fuse structure and a method of programming the same.

### BACKGROUND

Electrically programmable fuses (or, e-fuses) are conventionally integrated into a semiconductor integrated circuit (IC) as a link (or, strip) of conducting material (e.g. metal, poly-silicon, etc.) between respective terminal access pads. The resistance of the fuse is initially low, and commonly referred to as “closed” in circuit terminology. When a sufficiently large current (I_{fuse}) is applied between the first terminal and the second terminal, the metallic elements in the link are electrically migrated away or the link is thermally destroyed, thereby changing the resistance of the e-fuse to a much higher level, commonly referred to as “open” in circuit terminology. This technique is commonly referred to as programming the e-fuse. Determining whether the fuse has been programmed is conventionally performed using a separate sensing circuit.

In advanced technologies, for example, in 20 nanometer nodes and below, e-fuses are commonly formed using back-end-of-line (BEOL) or middle-of-line (MOL) thin metal films or via structures in a standard fin-shaped field effect transistor (FinFET) process flow with additional masking and processing steps. These conventional e-fuses utilize a salicide material (also referred to as self-aligned silicide). This salicide is formed entirely of a silicon base material converted to a silicide using a precursor metal and an annealing step. However, this salicide requires a high current level to program (or, blow) the e-fuse. Furthermore, these high current levels required to program (or, blow) the e-fuse are typically supplied by a blow-out current supplier ancillary to the structure containing the e-fuse. Therefore, if there is e-fuse circuit failure in a device in the field, the device most commonly needs to be returned to the manufacturer for repair.

### BRIEF SUMMARY

Time-dependent dielectric breakdown (TDDB) percolation current induced e-fuse structures and methods of programming the same are disclosed. In a first aspect of the disclosure, an e-fuse structure includes: a circuit including an e-fuse operably coupling the circuit to a power source, and a redundant circuit for operably coupling the power source in response to opening of the e-fuse, wherein the e-fuse opens in response to a time-dependent dielectric breakdown (TDDB) percolation current in proximity to the circuit migrating through the e-fuse.

A second aspect of the disclosure includes a method of programming an e-fuse structure, the method including: opening an e-fuse of a circuit in response to a time-dependent dielectric breakdown (TDDB) percolation current in proximity to the circuit migrating through the e-fuse, the e-fuse operably coupling the circuit to a power source, and coupling a redundant circuit to the power source in response to the opening of the e-fuse.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 depicts an e-fuse structure having an e-fuse containing circuit and redundant circuit, both circuits coupled to a power supply.

FIG. 2 depicts the travelling path of a time-dependent dielectric breakdown (TDDB) percolation current from a point of defect to an e-fuse.

FIG. 3 depicts misalignment of zero via layer via V0 to reduce a threshold power (Pₜₕᵣₑₛ) needed to create an open circuit.

FIG. 4 depicts an e-fuse structure having a plurality of e-fuse containing redundant circuits.

It is noted that the drawings of the invention are not necessarily to scale. The drawings are intended to depict only typical aspects of the invention, and therefore should not be considered as limiting the scope of the invention. In the drawings, like numbering represents like elements between the drawings.

### DETAILED DESCRIPTION

The subject matter disclosed herein relates to self-triggering e-fuses of semiconductors. More specifically, various aspects described herein relate to a time-dependent dielectric breakdown (TDDB) percolation current induced e-fuse structure and a method of programming the same.

As noted above, conventional e-fuses require a high current level to program (or, blow) the e-fuse and such current is typically supplied by a blow-out current supplier ancillary to the structure containing the e-fuse. Therefore, if there is e-fuse circuit failure in a device in the field, the device most commonly needs to be returned to the manufacturer for repair.

In contrast to such conventional e-fuse structures, the e-fuse structures according to embodiments of the disclosure utilize a blow-out current supplied directly by a TDDB event within the e-fuse structure itself. Such a “self-activated” or “self-triggering” e-fuse can be designed into individual logic and memory cells such that a defective cell within a circuit can be shut down while still allowing the remaining and/or redundant cells to continue their functions. Thus, e-fuse structures according to embodiments of the disclosure neither require an ancillary blow-out current supplier in order to program (or, open) the e-fuse nor require an ancillary sensing circuit in order to determine if the e-fuse has been programmed (or, opened) and if activation of one or more redundant cells is needed. Furthermore, since defective cells can be shut off automatically with e-fuse structures of the disclosure, there is no need for manufacturer repair of a failed part. Additionally, and somewhat surprisingly, such e-fuse structures of the disclosure benefit from reduction in circuit failure rate as well.

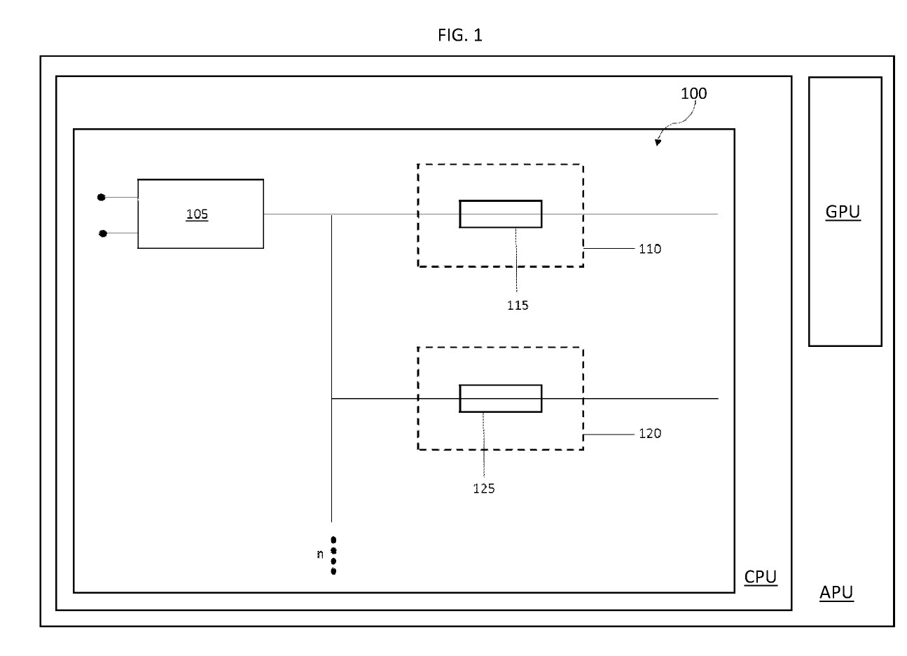

FIG. 1 depicts an e-fuse structure 100 including a circuit 110 including an e-fuse 115 operably coupling circuit 110 to a power source 105, and a redundant circuit 120 for operably coupling power source 105 in response to opening of e-fuse 115. E-fuse 115 opens in response to a time-dependent dielectric breakdown (TDDB) percolation current in proximity to circuit 110 migrating through e-fuse 115. Redundant circuit 120 can include an e-fuse 125.

E-fuse structures of the disclosure can include any number n (or, plurality) of redundant circuits. When a plurality of redundant circuits are present, the redundant circuits are sequentially activated in response to sequential e-fuse opening.

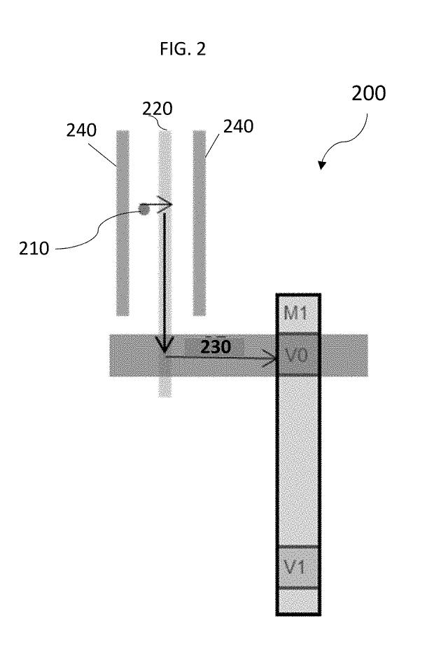

FIG. 2 depicts an e-fuse structure 200 showing the travelling path (arrows) of the time-dependent dielectric breakdown (TDDB) percolation current from a defect point 210 to an e-fuse in via layer V0. More specifically, the TDDB percolation current is generated at defect point 210 which is, in the example shown, in proximity to gate 220, migrates to gate 220, flows along gate 220 and to adjoining contact 230, and then flows along contact 230 and to the e-fuse. Upon migration of the TDDB percolation current through the e-fuse, the e-fuse opens. In FIG. 2, gate 220 is flanked by trench silicide 240, contact 230 connects with a first metal layer M1 by way of via layer V01, and M1 is in contact with a first via layer V1.

The noted TDDB percolation current has a value (in amperes) I_{percolation} (or I_{perc}). I_{percolation} relates to the threshold power (Pₜₕᵣₑₛ) needed to open the e-fuse (i.e. create an open circuit), said relationship being traditionally represented as follows

Pₜₕᵣₑₛ=V*I_{percolation}=V²/R

or alternately represented as follows

I_{percolation}=P_{threshold}/V

wherein Pₜₕᵣₑₛ is measured in Watts, V is the voltage measured in Volts and R is the resistance measured in Ohms (Ω). In some embodiments of the disclosure, Pₜₕᵣₑₛ is in the range of from about 0.00001 Watts to about 0.01 Watts. In various embodiments of the disclosure, V is in the range of from about 0.3 Volts to about 6.5 Volts. In other embodiments of the disclosure, Pₜₕᵣₑₛ is in the range of from about 0.0001 Watts to about 0.001 Watts. In other embodiments of the disclosure, V is in the range of from about 0.8 Volts to about 1.9 Volts.

As can be ascertained from the equation above, as the resistance increases, Pₜₕᵣₑₛ is reduced. It is also noted here that resistance increases as the critical dimension is decreased in every new technology node (see e.g., technology node 10 nanometers (nm), technology node 7 nm, etc.). Therefore, applicability of the e-fuse structures of the disclosure increases as the technology node advances. However, in older technology nodes, a mechanism for lowering Pₜₕᵣₑₛ is desirable.

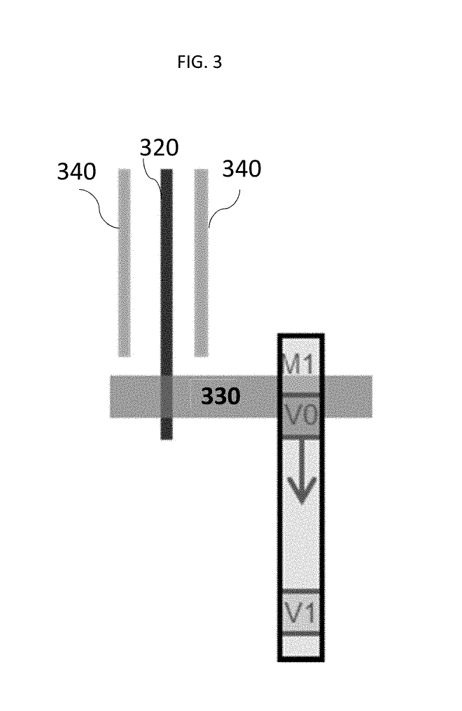

One mechanism for lowering Pₜₕᵣₑₛ is shown in FIG. 3. More specifically, FIG. 3 depicts intentional misalignment of zero via layer (e.g., V0) vias. With intentional misalignment, the via coverage area can be significantly smaller and thus easier for the TDDB percolation current to cause an open circuit (less power needed to melt the via). It should be noted however that the electromigration short length effect has to be utilized in this situation in order to prevent electrical/mechanical failure of the misaligned vias. Similar to FIG. 2, 340 refers to trench silicide, 320 refers to gate, 330 refers to contact, V0 refers to a zero via layer, V1 refers to a first via layer, and M1 refers to a first metal layer.

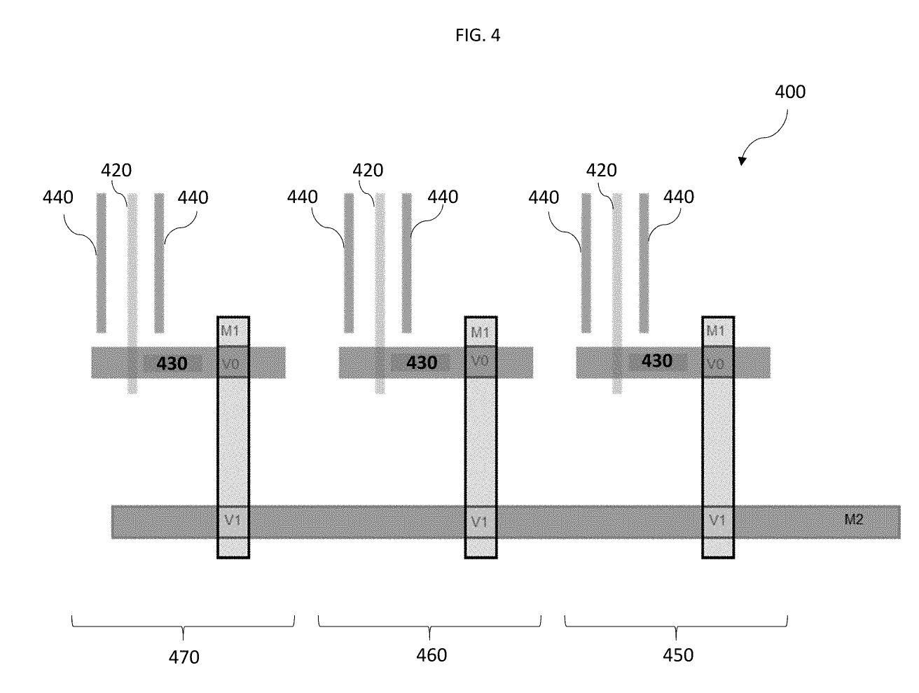

As mentioned above, e-fuse structures of the disclosure can include any number of redundant circuits. Different from FIGS. 1 to 3, FIG. 4 depicts an e-fuse structure 400 having a plurality of e-fuse containing redundant circuits 450/460/470. Redundant circuits 450/460/470 are each coupled to a second metal layer M2 by way of first via layer V1. V0 and M1 are as defined above with respect to FIG. 2. Redundant circuits 450/460/470 each contain a gate 420, a contact 430 and trench silicide 440 flanking gate 420.

In addition to the benefit of increased applicability of the e-fuse structures of the disclosure as the technology node advances, the inventors have discovered further benefits such as improved successive breakdown time and voltage.

More specifically, e-fuse structures according to the disclosure have improved variability. In other words, e-fuse structures according to the disclosure exhibit breakdown times that are successively improved due to successively lower variabilities. This suggests that a lifetime improvement on the scale of multiple orders of magnitude may be obtained.

It is noted that not only is the time to failure improved with the e-fuse structures according to the disclosure, but the breakdown voltage is improved as well. This provides for the redundant circuit of the e-fuse structure having a greater TDDB reliability than the circuit, and where the redundant circuit comprises a plurality of redundant circuits, each subsequent redundant circuit will have a greater TDDB reliability than a previous redundant circuit.

In light of the above, failure rate in the field of a device utilizing the e-fuse structures of the disclosure should be reduced significantly, even without 100% successful rate of e-fuse programming (or, opening) at every TDDB failure. Furthermore, even if only a portion of instances result in the e-fuse being triggered by TDDB percolation current, the product failure rate will still be reduced significantly. In other words, TDDB failure rate can only decrease by the adoption of the e-fuse structures of the disclosure.

The e-fuse structures according to embodiments of the disclosure allow for devices to achieve failure rates below 1 part per million (ppm). Thus, possible applications for the e-fuse structures of embodiments of the disclosure are in central processing units (CPUs) and accelerated processing units (APUs) (e.g., an APU comprising a CPU and a graphics processing unit (GPU)) which have extremely high requirements for reliability. Another possible application which also requires an extremely high requirement for reliability is an autonomous automobile.

Other possible end products utilizing the e-fuse structures of the disclosure can be any product that includes integrated circuit chips, ranging from toys and other low-end applications to advanced computer products having a display, a keyboard or other input device, and a central processor. Integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product.

In addition to the e-fuse structures disclosed herein, the present disclosure also relates to methods of programming e-fuse structures. A method of the disclosure includes opening an e-fuse of a circuit in response to a time-dependent dielectric breakdown (TDDB) percolation current in proximity to the circuit migrating through the e-fuse, the e-fuse operably coupling the circuit to a power source, and coupling a redundant circuit to the power source in response to the opening of the e-fuse.

The TDDB percolation current mentioned in the method of the disclosure has a value I_{percolation} (I_{perc}) as defined above. The redundant circuit mentioned in the method according to the disclosure can include a plurality of redundant circuits. If a plurality of redundant circuits are present, the method of the disclosure can further include sequentially coupling the redundant circuits to the power source in response to sequential e-fuse opening.

As explained above relating to the e-fuse structures of the disclosure, when the redundant circuit includes only one circuit, the redundant circuit has a greater TDDB reliability than the circuit, and when the redundant circuit includes a plurality of redundant circuits, a subsequent redundant circuit of the plurality of redundant circuits has a greater TDDB reliability than a previous redundant circuit of the plurality of redundant circuits.

The methods of the disclosure can also include, before the opening of the e-fuse by the TDDB percolation current, stressing of the e-fuse structure by applying a voltage to the e-fuse structure that is sufficient to cause failure of a plurality of circuits within the e-fuse structure. In other words, a device containing an e-fuse structure according to the disclosure can also be subject to a “burn-in” process at the manufacturing facility. While such burn-in may boost the TDDB reliability of e-fuses formed using BEOL or MOL thin metal films, the TDDB reliability of e-fuses formed using front-end-of-line (FEOL) thin metal films may be reduced.

The methods of the disclosure however do not require either applying an ancillary blow-out current to a circuit in order to open the e-fuse or employing an ancillary sensing circuit to determine if the e-fuse has been opened. This lack of utilizing an ancillary blow-out current and an ancillary sensing circuit is due to the above-mentioned “self-triggering” or “self-activating” nature of the e-fuse structure. More specifically, the methods of programming e-fuse structures according to embodiments of the disclosure utilize a blow-out current supplied directly by a TDDB event within the e-fuse structure itself. This means that an ancillary blow-out current is not needed to open (or, blow) the e-fuse of a circuit of a defective cell in order to shut down the defective cell because the TDDB percolation current performs the job. This also means that an ancillary sensing circuit is not needed to determine if an e-fuse has been opened and if a redundant circuit needs to be activated since the redundant circuit is configured to automatically activate in response to the e-fuse opening.

In light of the above-noted features, there is no need for a device to return to the manufacturer for repair upon TDDB breakdown, thus allowing for the programming method of the disclosure to occur within the device itself, i.e., repair itself, while still allowing the remaining parts of the device to operate.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

1. An e-fuse structure comprising:
a circuit including an e-fuse operably coupling the circuit to a power source; and
a redundant circuit for operably coupling the power source in response to opening of the e-fuse;
wherein the e-fuse opens in response to a time-dependent dielectric breakdown (TDDB) percolation current in proximity to the circuit migrating through the e-fuse.

2. The e-fuse structure of claim 1, wherein the redundant circuit has a greater TDDB reliability than the circuit.

3. The e-fuse structure of claim 1, wherein the redundant circuit comprises a plurality of redundant circuits, the plurality of redundant circuits being sequentially activated in response to sequential e-fuse opening.

4. The e-fuse structure of claim 3, wherein a subsequent redundant circuit of the plurality of redundant circuits has a greater TDDB reliability than a previous redundant circuit of the plurality of redundant circuits.

5. The e-fuse structure of claim 1, wherein the TDDB percolation current has a value (I_{percolation}):
I_{percolation}=P_{threshold}/V
wherein P_{threshold} is a power sufficient to open the e-fuse and is in the range of from about 0.00001 Watts to about 0.01 Watts and V is a voltage of the circuit and is in the range of from about 0.3 Volts to about 6.5 Volts.

6. The e-fuse structure of claim 1, wherein the e-fuse structure does not require an ancillary blow-out current supplier in order to open the e-fuse.

7. The e-fuse structure of claim 1, wherein the e-fuse structure does not require an ancillary sensing circuit in order to determine if the e-fuse has been opened.

8. A method of programming an e-fuse structure, the method comprising:
opening an e-fuse of a circuit in response to a time-dependent dielectric breakdown (TDDB) percolation current in proximity to the circuit migrating through the e-fuse, the e-fuse operably coupling the circuit to a power source; and
coupling a redundant circuit to the power source in response to the opening of the e-fuse.

9. The method of claim 8, wherein the redundant circuit has a greater TDDB reliability than the circuit.

10. The method of claim 8, wherein the redundant circuit comprises a plurality of redundant circuits, the method further comprising:
sequentially coupling the redundant circuits to the power source in response to sequential e-fuse opening.

11. The method of claim 10, wherein a subsequent redundant circuit of the plurality of redundant circuits has a greater TDDB reliability than a previous redundant circuit of the plurality of redundant circuits.

12. The method of claim 8, wherein the opening of the e-fuse does not comprise applying an ancillary blow-out current to the circuit and through the e-fuse.

13. The method of claim 8, wherein the method does not employ an ancillary sensing circuit to determine if the e-fuse has been opened.

14. The method of claim 8, wherein the TDDB percolation current has a value (I_{percolation}) sufficient to open the e-fuse:
I_{percolation}=P_{threshold}/V
wherein P_{threshold} is a power sufficient to open the e-fuse and is in the range of from about 0.00001 Watts to about 0.01 Watts and V is a voltage of the circuit and is in the range of from about 0.3 Volts to about 6.5 Volts.

15. The method of claim 8, further comprising, before the opening of the e-fuse by the TDDB percolation current:
stressing the e-fuse structure by applying a voltage to the e-fuse structure that is sufficient to cause failure of a plurality of circuits within the e-fuse structure.

16. A central processing unit (CPU) comprising an e-fuse structure and mounted onto a chip, the e-fuse structure comprising:
a circuit including an e-fuse operably coupling the circuit to a power source; and
a redundant circuit for operably coupling the power source in response to opening of the e-fuse;
wherein the e-fuse opens in response to a time-dependent dielectric breakdown (TDDB) percolation current in proximity to the circuit migrating through the e-fuse.

17. The CPU of claim 16, wherein the redundant circuit comprises a plurality of redundant circuits, the plurality of redundant circuits being sequentially activated in response to sequential e-fuse opening.

18. The CPU of claim 16, wherein the CPU has a failure rate of less than 1 parts per million (ppm).

19. An accelerated processing unit (APU) comprising the CPU of claim 16 and a graphics processing unit (GPU) mounted onto a chip.

20. The APU of claim 19, wherein the APU has a failure rate of less than 1 parts per million (ppm).
